(19) United States
(12) Patent Application Publication
(10) Pub. No.: US 2025/0036841 A1
(43) Pub. Date: Jan. 30, 2025

(54) Error Evaluation Platform using Field Programmable Gate Array Based Emulation

(71) Applicant: CARNEGIE MELLON UNIVERSITY, Pittsburgh, PA (US)

(72) Inventors: Ahmet Atli, Pittsburgh, PA (US); Prashanth Mohan, Pittsburgh, PA (US); Kenneth Mai, Pittsburgh, PA (US)

(73) Assignee: CARNEGIE MELLON UNIVERSITY, Pittsburgh, PA (US)

(21) Appl. No.: 18/783,641

(22) Filed: Jul. 25, 2024

Related U.S. Application Data
(60) Provisional application No. 63/528,812, filed on Jul. 25, 2023.

(51) Int. Cl. G06F 30/333; G06F 30/3323

(52) U.S. Cl. CPC G06F 30/333; G06F 30/3323

(57) ABSTRACT

Disclosed herein is a platform comprising a hardware compiler framework to directly instrument an RTL representation of an input design with a fault injection processor enabling the execution of arbitrary error injection requests from the user and communication with the design under test to target specific design sections for fault injection.

### RELATED APPLICATIONS

This application claims the benefit of U.S. Provisional Patent Application No. 63/528,812, filed Jul. 25, 2023, the contents of which are incorporated herein in their entirety.

### GOVERNMENT INTEREST

This invention was made with U.S. government support under contract DE-NA0003525, granted by the U.S. Department of Energy (DOE). The U.S. government has certain rights in this invention

### BACKGROUND

System-on-Chip (SoC) platforms are used widely to satisfy the computing needs of various devices ranging from low-power internet of things (IoT) devices to servers with high-performance requirements. These SoCs are being shaped by modern workloads and are becoming specialized with many hierarchies of buses, accelerator units, and peripherals.

With the emergence of artificial intelligence (AI) and machine learning (ML.) workloads, deep neural networks (DNNs) are one of the most common drivers of this trend. SoCs featuring DNN co-processors and accelerators are widely deployed in various fields such as healthcare, autonomous driving, and robotics.

DNNs are mathematical models that perform transformations on an input tensor to provide a higher-level representation. Most often, the DNNs are used in classification tasks where the input is the digital representation of an image or speech, and the output is the class label that the network assigns to the input. DNNs consist of multiple layers that perform a linear transformation determined by the layer type on the previous layer outputs and apply a non-linear activation at the end to feed into the next layer. DNNs that employ convolutional layers, convolutional neural networks (CNNs), are often used in image classification tasks. The weights in the convolutional layers work as image filters and are applied to the image by performing a multiply-accumulate (MAC) of the weight tensor with the input tensor within a sliding window.

DNNs can achieve high accuracy in image classification benchmarks. but they are computationally expensive. requiring billions of MAC operations per inference. To overcome this, specialized hardware accelerators for DNNs are currently being deployed in systems. DNN accelerators take advantage of the dataflows of underlying compute kernels to map the operation onto a spatial array of processing elements (PEs). One of the most common DNN accelerator architectures is the systolic array, which is the architecture often used in datacenter tensor processing units (TPU). In this architecture, the main operational blocks are a 2D array of PEs that compute the MAC and feed the results to their neighbors, a scratchpad that scores the weight and the input tensors, and an accumulator that stores the cumulative sum of the MAC operations done by the PE array.

The safety-critical nature of these applications drives the demand for comprehensive reliability analysis of SoCs. As with all integrated circuits (ICs), SoCs are susceptible to radiation-induced single-event upsets (SEUs) in their storage nodes during operation. For example, space agencies have started to deploy AI systems for space exploration, and as the demand for AI in space continues to increase, the reliability of the SoCs with accelerators becomes an increasingly important design requirement.

Fault injection (FI) experiments are frequently used to verify the reliability of ICs during pre-silicon design cycles. Such experiments are most often performed using resistor-transfer logic (RTL) cycle-accurate simulators, but these methods are prohibitively slow to characterize SoCs with large workloads like DNNs. Field programmable gate array (FPGA) emulation-based FI has been proposed as a way to accelerate these experiments, in which the designers instrument the target design and add the capability of dynamically injecting errors into storage nodes and logic elements.

### SUMMARY

Disclosed herein is a platform providing a method for emulation-based FI using field programmable gate arrays (FPGA) in which the designers instrument the target design and dynamically inject errors into storage nodes and logic elements. The platform comprises a resource-efficient, fast and programmable FI environment that makes use of the FPGA-based hardware emulation to run long test applications at near-silicon speeds.

The disclosed platform uses a hardware compiler framework to directly instrument a computer-readable description of the circuit design, for example, an RTL representation of the input design, rather than the synthesized gate-level netlist. Not lowering the design to the gate level preserves the high-level RTL abstractions such as arithmetic, bit shifts and FIFOs, which enables scalable instrumentation with less instrumentation overhead per flip-flop compared to prior art methods. The instrumented RTL is human-interpretable, easy to debug, and portable across different FPGA/emulation platform vendors.

The disclosed platform features stop-clock saboteurs, which offer negligible run-time impact (1-2 cycles/error) and flexibility by allowing injection of an arbitrary number of errors per program cycle This flexibility allows the platform to be the first tool to demonstrate error responses of multi-clock designs for both SRAM and FF soft errors and arbitrary multi-bit upset (MBU) patterns.

The platform inserts a user-programmable FI processor into the instrumented RTL, which can execute arbitrary error injection requests from the user and communicate with the design under test (DUT) to target specific program sections for FI. Also included is an FI instruction generator that can feed the processor with FI requests that mimic SEU patterns in radiation environments.

The platform provides a novel way for designers to pinpoint weak points in their RTL and aids with the design space exploration for SEU mitigation.

### BRIEF DESCRIPTION OF THE DRAWINGS

By way of example, a specific exemplary embodiment of the disclosed system and method will now be described, with reference to the accompanying drawings, in which:

FIG. 1 is a block diagram showing the workflow of the platform.

FIG. 2 is a schematic diagram showing instrumentation for an SRAM.

FIG. 3 is a schematic diagram showing instrumentation for a flip-flop.

FIG. 4 is a block diagram showing the operation of the FI processor.

FIG. 5 is a graphical depiction of the methodology of the present invention for converting uniform random errors into multi-bit upsets.

### DETAILED DESCRIPTION

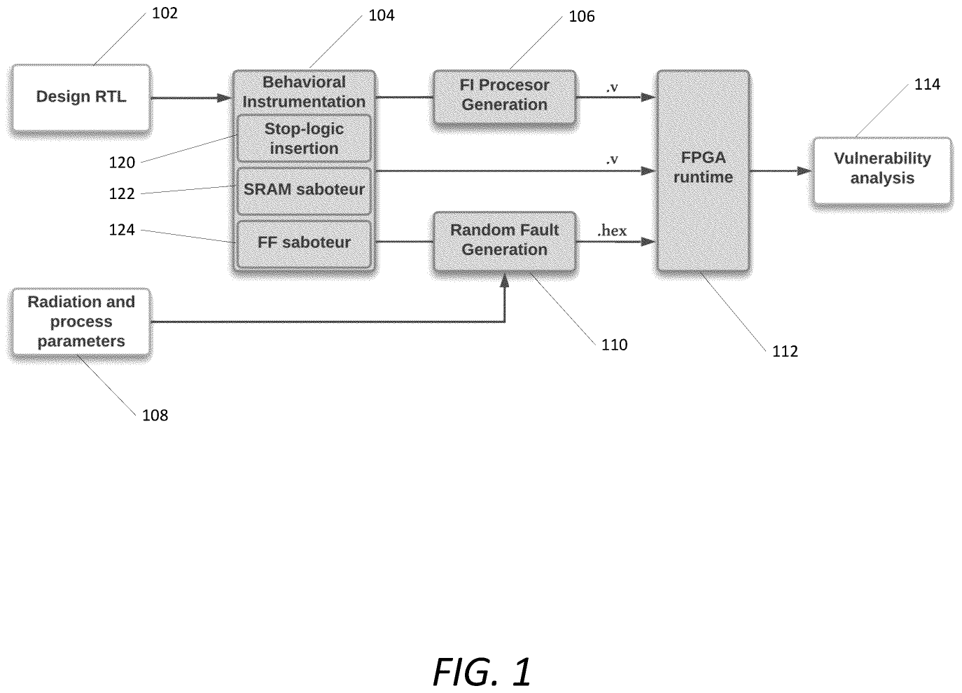

The platform uses a variety of tools and flows to transform an input RTL to an FI-instrumented and FI-programmable FPGA bitstream. The workflow with the major steps is summarized in FIG. 1. First, the user-specified SoC flow 102 is instrumented with saboteurs at 104. An FI processor 106 for programmable control is generated and FI instructions to inject random faults 110 according to radiation and process parameters 108 are generated. An FPGA runtime 112 with the faults inserted is generated and executed. A vulnerability analysis 114 may be generated by review of the results of FPGA runtime 112. As would be realized, any RTL may be instrumented through the flow.

Once the SoC design 102 is available, a series of transformations 120, 122 124, on the circuit representation are applied to add the saboteur logic. Stop-logic saboteur logic is added to the storage elements. Single-cycle bit-flip logic is added to flip-flops and 2-cycle read-modify-write (RMW) logic is added to SRAM memories.

In one embodiment, the Flexible Intermediate Representation for RTL (FIRRTL) hardware compiler framework is used to perform the desired transforms, but other compliers may also be used. FIRRTL is an intermediate representation (IR) for digital circuits designed as a platform for writing circuit-level transformations. FIRRTL, unlike logic synthesis, keeps behavioral RTL abstractions. This means that the output RTL is easier to debug, interpret and map onto FPGA hard macros such as DSPs, ALUs and BRAMs efficiently.

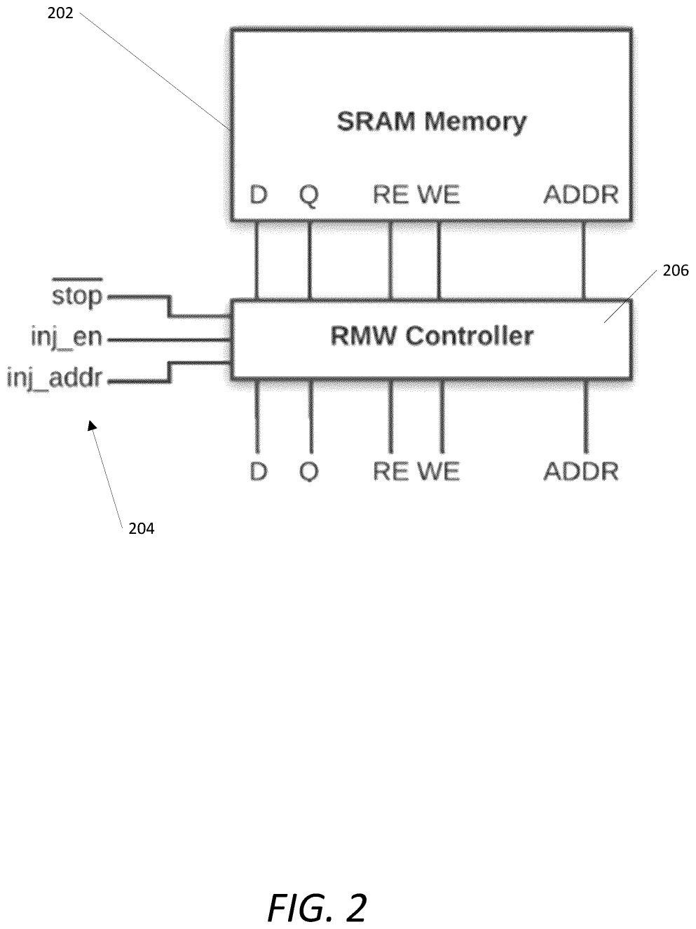

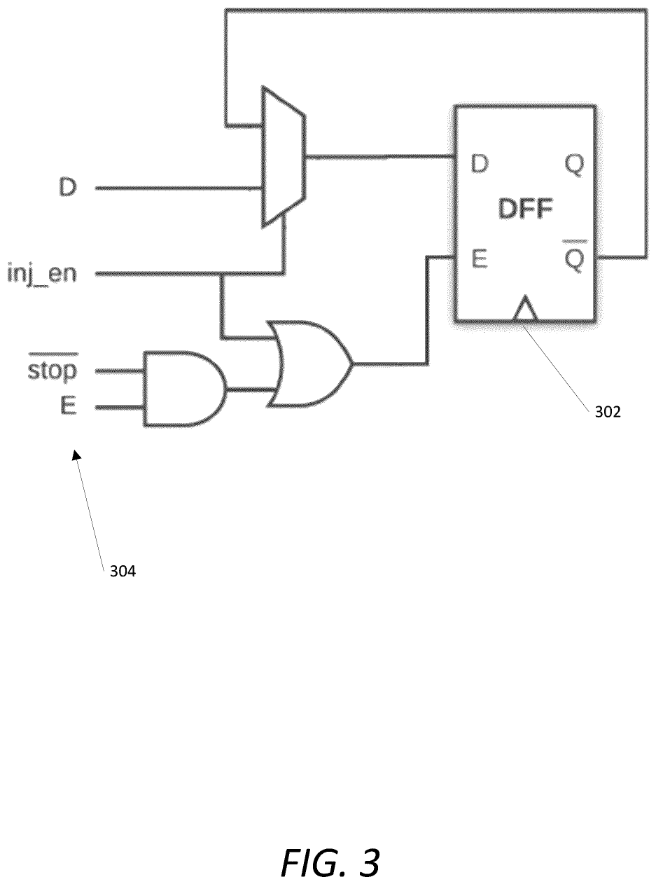

FIG. 2 and FIG. 3 show the details of the saboteur approach, showing the instrumentation 204, 304 for an SRAM 202 and Flip-Flop 302 respectively. The storage elements in the design receive the following control signals to manage their FI requirements: inj_en decides whether an error will be injected to that element in the given cycle; inj_addr chooses the bit location of the error to be injected (Note that this input is only present in multi-bit elements like SRAM macros and not single flip-flops); stop_clock gates every storage element during FI except for the FI target. This signal is unique per clock domain.

FIG. 2 shows a diagram of how SRAM main memories are instrumented. Because the individual SRAM bits are not controllable, a given bit is injected into using a stop-clock read-write-modify (RMW) approach controlled by RWM controller 206. When stop is raised and FI is in progress to another element, the controller gates the read-enable and write-enable pins of the macro. If inj_en is also high while stop is high, the controller takes control of the macro read/write ports. In the first cycle, the controller reads the word that contains the bit at the address specified by the inj_addr signal. In the second cycle, the controller inverts the targeted bit in the read port and writes it back to the same address, effectively flipping a single bit at the memory array within two cycles. At the third cycle, the control goes back to the SoC, and the program continues executing with the same system microarchitectural state, except for the targeted bit. Note that, during the fault injection, any program may be executed by the SoC.

The injection process for flip-flops is detailed in FIG. 3. The idea is very similar to the SRAM injection, but with flip-flops there is no need for a read operation, as the outputs of a flip-flop is available at every cycle. Injecting to the flip-flop stops the clock for one cycle, where the inverted output bit is fed to the data pin of the flip-flop, and the enable is asserted high to make sure that the write goes through. It is worth noting that the stop-clock FI approach allows significant flexibility at the fault generation and control compared to prior-art methods. An arbitrary number of faults can be injected at any cycle, which allows modeling MBU effects and high BER FI experiments.

The flow inserts a FI processor at the top hierarchy of the generated FI-instrumented RTL design. The FI processor sequentially reads the parameters of the program execution from a memory and injects errors in the specified locations at specified cycles. FI can be paused/started through software to target specific subroutines within a program.

The purpose of the FI processor is to read in the user instructions and inject errors into the specified locations at the specified cycles by driving the FI control signals. The FI processor is designed to have high programmability to enable a diverse range of experiments to be designed and performed. The power of programmability allows the error model and the error rates of different design elements and software blocks to be changed independently for each experiment.

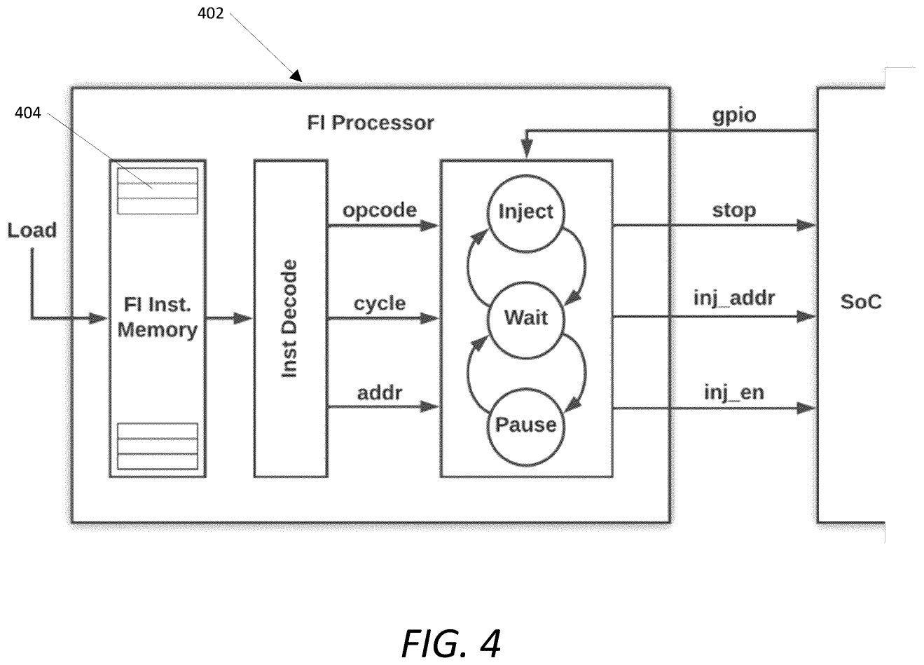

FIG. 4 is a block diagram showing the operation of the FI processor 402. The user loads the FI memory with the instructions 404 before the execution of the SoC program starts. The supported instructions are injff, injsram, wfi and pause. The injff and injsram instructions specify the cycle count and the bit position that the FI processor uses to wait and then raise the corresponding FI control signal to inject to flip-flops (injff) and SRAM (injsram) respectively. The wfi instruction forces the FI processor to wait until the specified interrupt IO is raised from the SoC. This creates a feedback path from the software running on the SoC to the FI subsystem, which enables localization of the injections to particular sections of the code for software resilience analysis. The pause instruction is used to raise stop for all the clock domains in the SoC under test, which is useful for external user interference in the experiment such as reloading the FI memory.

The platform provides a custom Python-based FI instruction generator library. The generator is designed to mimic soft errors due to radiation, but the user may choose to write their own instructions to exercise any fault pattern they would like to exercise on their circuit. The instruction generator parses the SoC fault instrumentation data to construct an internal graph representation of the RTL module hierarchies and fault-injectable components. The following user specifications are used to generate the FI instructions for an experiment: (1) the design hierarchies to inject errors into; (2) the storage element type (FF vs SRAM); (3) the multi-bit upset (MBU) probability; (4) the SRAM bit error rate; (6) the flip-flop bit error rate; (7) the begin/end cycles; and (8) a random seed.

The instruction generator uses bit error rate (BER) to specify the sensitivity of the storage nodes to the radiation. BER describes the probability that an SEU happens to a storage bit in one clock cycle. BER can be calculated using DUT clock period T, the radiation flux ϕ and the vulnerable bit cross-section σ_{bit} as follows:

$$B E R = {σ}_{b i t} ϕ T$$

Given the BER and the target design hierarchies, the generator calculates the number of errors to be injected (N) by drawing a sample from the binomial distribution B(n, p) where the sample size n is the product of the number of cycles and the total number of vulnerable bits, and p is the specified BER. Every error is assigned a cycle uniformly randomly, which creates a list of tuples of (bitᵢdx, cycle) that can be compiled into the FI processor binary. Uniform randomness is assumed in the time (cycle index) and space (vulnerable bit index). This assumption can be modified to model environments with non-uniform radiation patterns such as ion beam pulses, or systems with different vulnerabilities for different design modules such as chiplet-based designs.

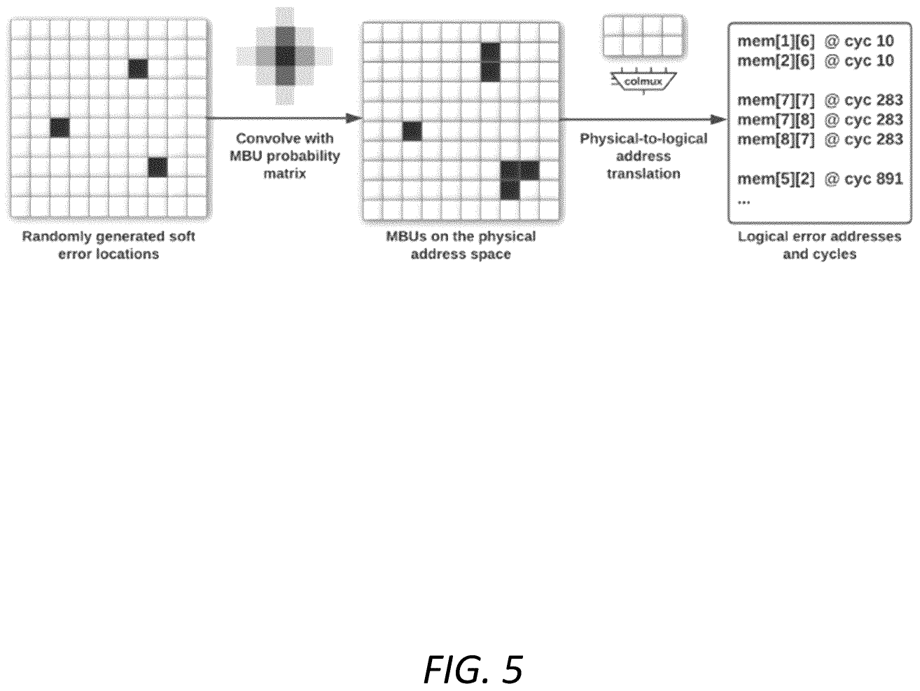

After the initial error event database is generated, the database is augmented with memory MBUs. The process is summarized in FIG. 5. MBU generation requires an MBU probability matrix that describes the probability that a given bit-flip at a location in memory will be accompanied with additional bit flips in the row-axis and the column-axis. This information is assumed to be characterized for the target radiation environment, similarly to BER. The MBU probability matrix given can contain information about neighbors that are 1 bit away, 2 bits away or any number of bits away from the error location, which can model large MBU trends seen in the latest process nodes.

The extra errors due to MBU effects are generated by convolving the probability matrix is with the generated errors and flipping the neighboring bits in the physical address space of the memory with probabilities specified in the input MBU characterization matrix. The additional errors are assigned the same cycle time as the error event that generated them. Thanks to the stop-clock injection method, an arbitrary number of bit errors can be injected such that they manifest in the same cycle from the application's perspective. Finally, the physical locations of the generated extra errors are translated to logical addresses using the column-muxing information of the target memories, which models the effects of bit interleaving.

After aggregating all FI requirements for an experiment, the generator emits a binary that can be interpreted by the FI processor. It also emits a human-readable assembly-like file format that can be used for debugging purposes. For very long applications, large SoCs, and high error rates, the binary may exceed the FI processor memory size. The binary can be divided into multiple chunks and the memory fed iteratively as the processor works through the instructions, which enables the processor to inject errors indefinitely with a low memory footprint on the emulation platform.

As would be realized by one of skill in the art, the methods described herein can be implemented on a system comprising a processor and memory, storing software that, when executed by the processor, implements the described methods.

As would further be realized by one of skill in the art, many variations on implementations discussed herein which fall within the scope of the invention are possible. Moreover, it is to be understood that the features of the various embodiments described herein were not mutually exclusive and can exist in various combinations and permutations, even if such combinations or permutations were not made express herein, without departing from the spirit and scope of the invention. Accordingly, the method disclosed herein is not to be taken as a limitation on the invention but as an illustration thereof. The scope of the invention is defined by the claims which follow.

1. A method comprising:
receiving a design specification for a chip or part of a chip;
instrumenting the design with one or more saboteurs for SRAM and flip-flop elements of the design;
generating a user-programmable fault injection processor;
generating one or more random faults, based on a set of parameters;
generating an executable runtime version of the design based on the instrumented design, the fault injection processor and the one or more random faults; and
executing a program on the executable runtime version.

2. The method of claim 1 further comprising:
determining any deviations in an expected outcome of executing the program.

3. The method of claim 1 wherein the design is an RTL-level description of the circuit.

4. The method of claim 1 wherein the fault injection processor executes arbitrary user-specified error injection requests.

5. The method of claim 1 wherein each of the saboteurs for the SRAM elements of the design comprises:
a read-write-modify controller controlled by:
an enable input indicating if an error should be injected into a specific SRAM element during a given cycle of the program execution;
an address input indicating a bit location in the SRAM element where the fault is to be injected; and
a stop input halting execution for all circuit elements except for the SRAM element where a fault is to be injected;
wherein the read-write-modify controller gates the read and write enable inputs of the SRAM memory based on the enable input and the stop input.

6. The method of claim 5 wherein:
in a first execution cycle the read-write-modify controller reads a word from the SRAM containing the bit location;
in a second execution cycle, the read-write-modify controller inverts the bit location; and
in a third cycle, the read-write-modify controller returns execution control to the chip or part of a chip.

7. The method of claim 1 wherein each of the saboteurs for the flip-flop elements of the design comprises:
circuitry, taking as input:
an enable input indicating if an error should be injected into a specific flip-flop element during a given cycle of the program execution; and
a stop input halting execution for all circuit elements except for the flip-flop element where a fault is to be injected.

8. The method of claim 7 wherein:
in a single execution cycle, an inverted output bit of the flip-flop is fed to a data input of the flip-flop, and the flip-flop enable is asserted.

9. The method of claim 1 wherein execution of the program is stopped while faults are injected at one or more SRAM and/or flip-flop elements of the chip or part of a chip.

10. The method of claim 9 wherein faults may be injected to multiple SRAM and/or flip-flop elements simultaneously.

11. The system of claim 1 wherein the fault-injection processor is generated at a top hierarchy of the instrumented design.

12. The method of claim 1 wherein the fault injection processor injects faults into specific circuit elements at specified cycles, based on programmable user instructions.

13. The method of claim 12 wherein the programmable user instructions include instructions indicating which elements should be fault injected during which cycle of program execution.

14. The method of claim 1 further comprising:
generating fault instructions mimicking soft errors due to exposure of the chip or part of a chip to radiation;
wherein the generated fault instructions are based on a set of user parameters including one or more of: the design hierarchy to inert error into, a storage element type, probability of a multi-bit upset error; SRAM bit error rate, flip-flop bit error rate, beginning and ending cycles and a random seed.

15. The method of claim 14 wherein the SRAM and flip-flop bit error rates specific sensitivity of the SRAM and flip-flop circuit elements to radiation, respectively.

16. The method of claim 15 wherein generating fault instructions comprises:
calculating a number of errors to be injected based on a binomial distribution as a function bit error rates and sample size.

17. The method of cli 16 wherein each generated fault instruction is assigned a cycle number and a bit index in the design with uniform probability.

18. The method of claim 16 further comprising:
generating a probability matrix indicating a probability that a given bit-flip at a specific location in the in the circuit will be accompanied by additional bit-flips neighboring bits;
convolving the probability matrix with a matrix indicating randomly selected soft error locations; and
flipping neighboring bits in the circuit with probabilities indicated by the convolution.

19. The method of claim 3 wherein the design is instrumented using FIRRTL.
